(19) United States
(12) Patent Application Publication
(10) Pub. No.: US 2002/0089066 A1
(43) Pub. Date: Jul. 11, 2002

(54) Method and system for decapsulating a multi-chip package

(76) Inventors: Mohammad Massoodi, Los Altos, CA (US); Mehrdad Mahanpour, Union City, CA (US)

Correspondence Address: Joseph A. Sawyer Jr., SAWYER LAW GROUP LLP, P.O. Box 51418, Palo Alto, CA, 94303, US

(21) Appl. No.: 09/759,963

(22) Filed: Jan. 11, 2001

(51) Int. Cl. H01L 23/48; H01L 23/52; H01L 29/40; H01L 21/44

(52) U.S. Cl. 257/777; 438/109

(57) ABSTRACT

A method and system for decapsulating a multi-chip package is disclosed. The multi-chip package includes a first die and a second die. The first die resides above the second die. The method and system include mechanically removing at least a portion of the first die substantially without destroying the portion of a second die. The method and system also include removing a portion of the multi-chip package between the first die and the second die to expose a portion of the second die substantially without destroying the portion of a second die.

### FIELD OF THE INVENTION

The present invention relates to semiconductor devices, and more particularly to a method and system for decapsulating a multi-chip package.

### BACKGROUND OF THE INVENTION

Currently, multi-chip packages are utilized for a variety of applications. FIG. 1 is a cross-section of a multi-chip package 10. The multi-chip package 10 holds a first semiconductor die 30 and a second semiconductor die 40. The dies 30 and 40 each include circuits (not explicitly shown) which could carry out a variety of functions. For example, the first die 30 might be a Flash die, while the second die 40 might be an SRAM die. Each die 30 and 40 has bond pads 32 and 33 and 42 and 43, respectively. The first die 30 resides on top of and is typically smaller than the second die 40. Because the area of the first die 30 is smaller than that of the second die 40, electrical connection can be made relatively easily to the bond pads 32 and 33 and 42 and 43 through the bond wires 34 and 35 and 44 and 45, respectively. Typically, the bond wires 34 and 35 and 44 and 45 are composed of gold.

The multi-chip package 10 includes a molding compound 12, solder bumps 14, copper foil 16 and 18, an adhesive layer 20 and a substrate 22. Note that for clarity, not all portions of the multi-chip package 10 are shown. The molding compound 12 encapsulates the first die 30 and second die 40. The adhesive layer 20 separates the first die 30 from the second die 40 and can be used to fix the first die 30 in position, above the second die 40. The adhesive layer 20 typically includes epoxy.

In order to make electrical connection to the circuits in the dies 30 and 40, bond wires 34 and 35 and 44 and 45, respectively, couple the bond pads 32 and 33 and 42 and 43, respectively, to the copper foil 18. Electrical contact is made to the solder bumps 14 through the copper foil 16. Using the solder bumps 14, electrical contact can be made to devices outside of the multi-chip package 10 and power can be provided to the multi-chip package 10.

Often, the circuits in the dies 30 and 40 of the multi-chip package 10 include one or more faults. In order to investigate the nature of the faults, the multi-chip package 10 is deprocessed. During deprocessing, the first die 30 or the second die 40 is to be exposed for testing.

FIG. 2 depicts a conventional method 50 for deprocessing the multi-chip package 10. The molding compound 12 above the first die 30 is removed, via step 52. Thus, the top surface of the first die 30 can be exposed for testing. This may be accomplished without damaging the bond pads 32 and 33, allowing electrical tests to be performed and power to be provided to circuits in the first die 30. Thus, the first die 30 may be tested, via step 54. However, an investigator may also desire to test the second die 40. In order to do so, some or, more typically, all of the first die 40 must be removed. Consequently, a wet etch is performed to remove the first die, via step 56. The wet etch also typically etches through the adhesive layer 20 between the first die 30 and the second die 40. Thus, the top surface of the second die 40 is exposed. The second die 40 may then be tested, via step 58.

Although the conventional method 50 allows the multi-chip package 10 to be decapsulated, one of ordinary skill in the art will readily realize that it is often difficult to expose the second die 40 for investigation. The wet etch performed in step 58 is difficult to control. Consequently, the wet etch often removes a portion of the second die 40. This makes further investigation of the second die 40 impossible. In addition, the etchant used in the wet etch typically acts isotropically. Thus, in addition to removing a portion of the second die 40, the wet etch may remove portions of the bond pads 42 and 43 or bond wires 44 and 45 even when the second die 40 itself is not significantly damaged. Consequently, further investigation of the second die 40 may be difficult or impossible even when the die 40 itself is substantially intact.

Accordingly, what is needed is a system and method for decapsulating a multi-chip package which allows both chips in the package to be deprocessed. The present invention to addresses such a need.

### SUMMARY OF THE INVENTION

The present invention provides a method and system for decapsulating a multi-chip package. The multi-chip package includes a first die and a second die. The first die resides above the second die. The method and system include mechanically removing at least a portion of the first die substantially without destroying the portion of a second die. The method and system also include removing a portion of the multi-chip package between the first die and the second die to expose a portion of the second die substantially without destroying the portion of a second die.

According to the system and method disclosed herein, the present invention provides the ability to investigate the properties of the second, lower die in a multi-chip package without destroying the second die during exposure of the second die.

### BRIEF DESCRIPTION OF THE DRAWINGS

FIG. 1 is a diagram of a multi-chip package

FIG. 2 is a flow chart depicting a conventional method for decapsulating a multi-chip package.

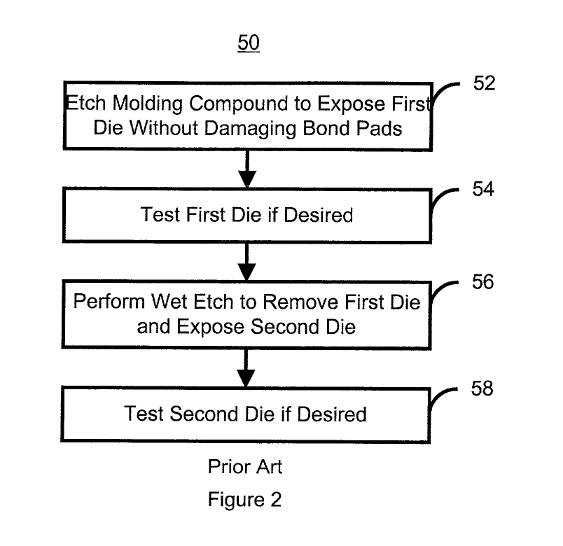

FIG. 3 is a high-level flow chart of a method in accordance with the present invention for decapsulating a multi-chip package.

FIG. 4 is a more detailed flow chart of a method in accordance with the present invention for decapsulating a multi-chip package.

FIG. 5 is a diagram of one embodiment of the multi-chip package after decapsulation using the method in accordance with the present invention.

FIG. 6 is a diagram of one embodiment of a receptacle in accordance with the present invention for holding a multi-chip package during deprocessing.

### DETAILED DESCRIPTION OF THE INVENTION

The present invention relates to an improvement in deprocessing of semiconductor devices. The following description is presented to enable one of ordinary skill in the art to make and use the invention and is provided in the context of a patent application and its requirements. Various modifications to the preferred embodiment will be readily apparent to those skilled in the art and the generic principles herein may be applied to other embodiments. Thus, the present invention is not intended to be limited to the embodiment shown, but is to be accorded the widest scope consistent with the principles and features described herein.

Multi-chip packages carry more than one semiconductor die. The semiconductor dies are typically stacked on top of each other. Thus, a first die typically resides on a second die. In order to examine faults within the circuits of the dies of the multi-chip package, the multi-chip package is deprocessed. Thus, to study the second die, the first die must be removed. In order to remove the first die, a wet etch is typically performed. However, one of ordinary skill in the art will realize that the wet etch often removes a portion of the second die in addition to the first die. As a result, the circuits in the second die cannot be further examined.

The present invention provides a method and system for decapsulating a multi-chip package. The multi-chip package includes a first die and a second die. The first die resides above the second die. The method and system include mechanically removing at least a portion of the first die substantially without destroying the portion of a second die. The method and system also include removing a portion of the multi-chip package between the first die and the second die to expose a portion of the second die substantially without destroying the portion of a second die.

The present invention will be described in terms of specific tools, such as a Chip Unzip machine. However, one of ordinary skill in the art will readily recognize that this method and system will operate effectively for other tools. Furthermore, the present invention is described in the context of a multi-chip package having two dies. However, one of ordinary skill in-the art will readily realize that the present invention is consistent with multi-chip packages having another number of dies.

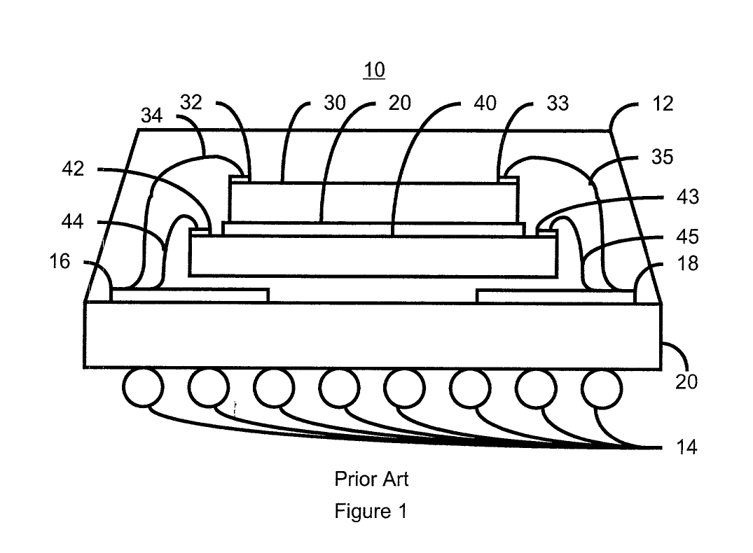

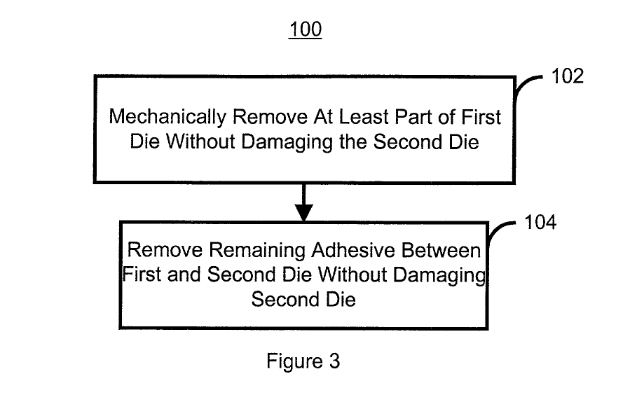

To more particularly illustrate the method and system in accordance with the present invention, refer now to FIG. 3, depicting a high-level flow chart of one embodiment of a method 100 in accordance with the present invention for deprocessing a multi-chip package. The method 100 will be described in conjunction with the multi-chip package 10 depicted in FIG. 1. At least a portion of the first die 30 is mechanically removed substantially without destroying the portion of a second die 40, via step 102. Preferably, step 102 includes milling the first die 30 as well as a portion of the adhesive layer 20 between the first die 30 and the second die 40. In one embodiment, Step 102 can remove the first die 30 without damaging the second die 40 because the thickness of the first die 30 is known. In such an embodiment, the milling is performed for a specific amount of time corresponding to the thickness of the first die 30. Thus, damage to the second die can be mitigated or prevented. A portion of the multi-chip package 10 between the first die 30 and the second die 40 is removed to expose a portion of the second die 40 substantially without destroying the portion of a second die 40, via step 104. Preferably, step 104 includes what remains of the etching the adhesive layer 20 after step 102 is completed. In a preferred embodiment, the etch utilizes an oxygen plasma. Note that if there are more than two dies 30 and 40 present in the multi-chip package, the method 100 can be repeated for each new die to be exposed. Thus, the die currently exposed can be mechanically removed, then the portion of the multi-chip package between the die removed and a subsequent die can be removed.

Thus, the first die 30 is mechanically etched in step 102 without damaging the second die 40. Consequently, the second die 40 can be exposed without damage to the die 40 and its circuits. As a result, the circuits in the second die 40 can be studied. Thus, faults in the second die 40 can be located and processing of the second die 40 and the multi-chip package 10 changed to account for the faults.

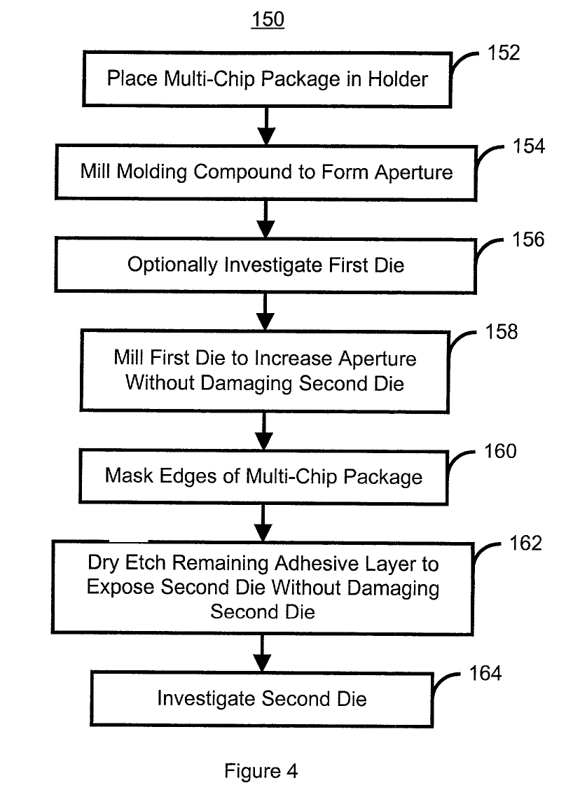

FIG. 4 depicts a more detailed flow chart of one embodiment of a method 150 in accordance with the present invention for deprocessing a multi-chip package. The method 150 will be described in the context of the multi-chip package 10 depicted in FIG. 1. Referring to FIGS. 1 and 4, the multi-chip package 10 is placed in a holder, via step 152. The holder should include a cavity for the multi-chip package 10. The cavity should be approximately the same size as the multi-chip package 10. A cavity of this size helps ensure that a plasma etch, described below, can be carried out without damaging other portions of the multi-chip package 10, such as the side of the multi-chip package 10 including the solder balls 14. The holder is preferably composed of Teflon.

The molding compound 12 above the first die 30 is milled away to provide an aperture in the multi-chip package 10, via step 154. Preferably, the molding compound 12 is milled using a cross cut end mill. Thus, the top surface of first die 30 is exposed by step 154. In a preferred embodiment, the cross cut end mill does not mill through the first die 30. In other words, the cross cut end mill only mills through the material for the first die 30, silicon, very slowly. Thus, little or no damage may be done to the first die 30 by removal of a portion of the molding compound 12. The first die 30 may optionally be investigated, via step 156. However, in a preferred embodiment, the aperture in the molding compound 12 is larger than the first die 30. Thus, the bond pads 32 and 33 and a portion of the bond wires 34 and 35 will be removed in step 154. Consequently, the first die 30 will preferably not be investigated.

The first die 30 is then milled to deepen the aperture and substantially without damaging the second die, via step 158. The first die 30 is preferably milled using a diamond cut mill. In addition, the first die 30 is preferably completely removed in step 158 to expose the largest area of the second die 40 possible. The first die 30 can be milled substantially without damaging the second die because the thickness of the first die 30 is generally known and because the removal of the molding compound 12 in step 154 stopped approximately at the surface of the first die 30. Thus, the first die 30 is preferably milled in step 158 for a time that is sufficient to mill through the thickness of the first die 30, but not long enough to damage the second die 40. In addition to milling the first die 30 is step 158, a portion of the adhesive layer 20 is generally milled.

The edges of the multi-chip package 10 are then masked, via step 160. In a preferred embodiment, step 160 masks approximately two millimeters of the edge of the multi-chip package 10. The edges of the multi-chip package 10 are masked to ensure that the edges are not etched during the method 150. This ensures that the multi-chip package 10 can still be secured in a testing socket for electrical evaluation after the method 150 has been completed.

The remainder of the adhesive layer 20 is then removed, via step 162. Typically, the residue of the adhesive layer 20 is removed by an etch using oxygen plasma. Thus, the second die 40 is exposed for study. The second die 40 may then be tested, via step 162. Thus, the multi-chip package 10 can be decapsulated without substantially damaging the second die 40. Consequently, the second die 40 can be exposed without damage to the die 40 and its circuits. As a result, the circuits in the second die 40 can be studied. Thus, faults in the second die 40 can be located and processing of the second die 40 and the multi-chip package 10 changed to account for the faults.

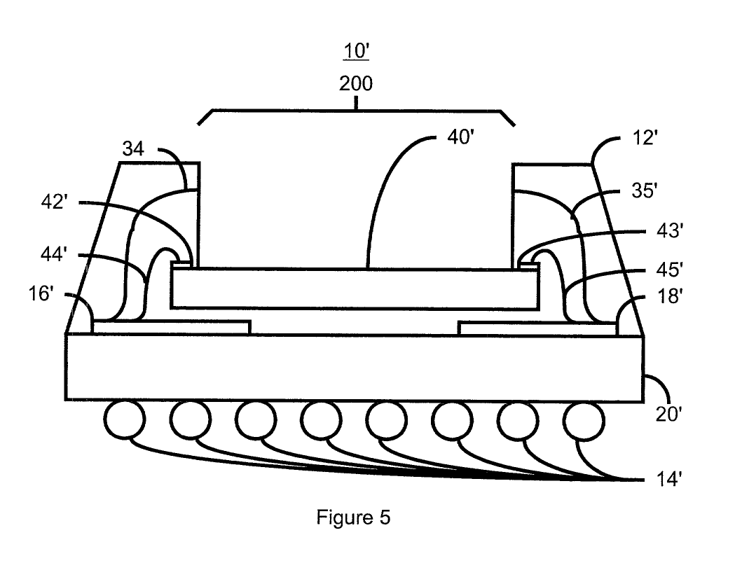

FIG. 5 depicts the multi-chip package 10′ after decapsulation using the method 100 or 150. Note that in the multi-chip package 10′, the first die 30 (not shown) was completely removed. The multi-chip package 10′ includes an aperture 200 which exposes the surface of the second die 40′ without damaging the bond wires 44′ and 45′ or the bond pads 42′ and 43′. Thus, the second die 40′ can be further studied.

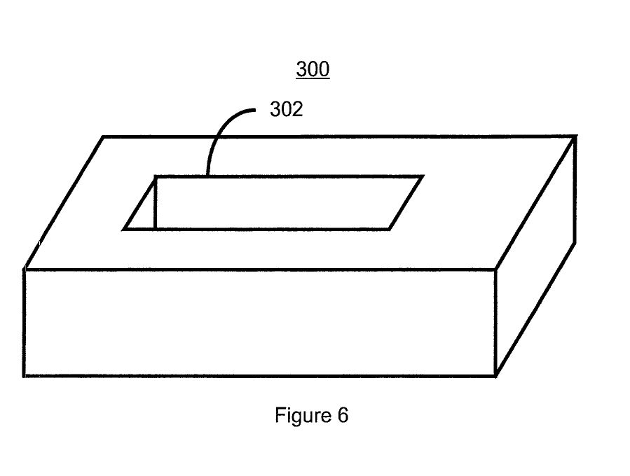

FIG. 6 depicts one embodiment of a holder 300 that can be used in the method 150 described in FIG. 4. Referring back to FIG. 6, the holder 300 includes a cavity 302. The cavity 302 is shaped to have dimensions that are close to those of the multi-chip package 10 or 10′. This allows the multi-chip package 10 or 10′ to be etched, for example using oxygen plasma, without significantly exposing the sides of the multi-chip package 10 or 10′ to the dry etch. Consequently, the portions of the multi-chip package 10 or 10′ not specifically desired to be removed can be preserved.

A method and system has been disclosed for deprocessing a semiconductor device. Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for decapsulating a multi-chip package including a first die and a second die, the first die residing above the second die, the method comprising the steps of:
(a) mechanically removing at least a portion of the first die substantially without destroying the portion of a second die; and
(b) removing a portion of the multi-chip package between the first die and the second die to expose a portion of the second die substantially without destroying the portion of a second die.

2. The method of claim 1 wherein the second die further includes a plurality of bond pads, wherein multi-chip package further includes a plurality of bond wires coupled to the plurality of bond pads, the plurality of bond wires for electrically connecting the second die to the multi-chip package and wherein the removing step (b) further includes the step of:
(b1) removing the portion of the multi-chip package between the first die and the second die to expose the portion of the second die without destroying the plurality of bond pads.

3. The method of claim 1 wherein the multi-chip package further includes a layer of adhesive disposed between first die and the second die and wherein the removing step (b) further includes the step of:
(b1) dry etching at least a portion of the adhesive.

4. The method of claim 1 wherein the mechanical removing step (a) further includes the step of:
(b1) milling with diamond cut mill.

5. The method of claim 1 wherein the multi-chip package includes molding compound above the first die and wherein the method further includes the step of:
(c) mechanically removing the molding compound using a cross cut end mill.

6. The method of claim 1 wherein the multi-chip package further has a plurality of edges and wherein the method further includes the step of:
(c) placing the multi-chip package in holder; and
(d) masking a second portion of the multi-chip package in proximity to a portion of the plurality of edges.

7. A method for decapsulating a multi-chip package including a first die and a second die having a plurality of bond pads and molding compound, the first die residing above the second die, the molding compound being above first die, the second die being electrically connected to the multi-chip package through the plurality of bond pads, the multi-chip package having a plurality of edges, the method comprising the steps of:
(a) placing the multi-chip package in holder;
(b) masking a second portion of the multi-chip package in proximity to a portion of the plurality of edges
(c) mechanically removing the molding compound using a cross cut end mill;
(d) mechanically removing at least a portion of the first die substantially without destroying the portion of a second die; and
(e) removing a portion of the multi-chip package between the first die and the second die to expose a portion of the second die substantially without destroying the portion of a second die.

8. A decapsulated multi-chip package for holding a first die and a second die residing below the first die, the decapsulated multi-chip package comprising:
the second die;
molding compound; and
a portion of the multi-chip package between the first die and the second die, the molding compound and the portion of the multi-chip package between the first die and the second die having an aperture therein, the aperture being formed using a mechanical process to remove a portion of the molding compound and at least a portion of the first die, and the portion of the multi-chip package, a portion of the second die being exposed by the aperture, the portion of the second die being exposed in the aperture substantially without destroying the portion of a second die.

9. The decapsulated multi-chip package of claim 8 wherein the second die further includes a plurality of bond pads, wherein multi-chip package further includes a plurality of bond wires coupled to the plurality of bond pads, the plurality of bond wires for electrically connecting the second die to the multi-chip package and wherein the aperture is formed by mechanically removing the portion of the multi-chip package between the first die and the second die to expose the portion of the second die without destroying the plurality of bond pads.

10. The decapsulated multi-chip package of claim 8 wherein the portion of the multi-chip package further includes a layer of epoxy disposed between first die and the second die.

11. The decapsulated multi-chip package of claim 1 wherein the aperture is formed using a mill.

12. The decapsulated multi-chip package of claim 11 wherein the at least the portion of the first die is removed using a diamond cut mill.
